(19) United States
(12) Patent Application Publication
(10) Pub. No.: US 2026/0161868 A1
(43) Pub. Date: Jun. 11, 2026

(54) TEMPLATE GENERATION FOR STORING REGISTER TRANSFER LEVEL (RTL) CODE OBJECTS

(71) Applicant: Singularity Dynamics Private Limited, Bangalore (IN)

(72) Inventor: Harish Kumar, Bangalore (IN)

(21) Appl. No.: 19/416,104

(22) Filed: Dec. 11, 2025

Related U.S. Application Data
(60) Provisional application No. 63/730,505, filed on Dec. 11, 2024.

(51) Int. Cl. G06F 30/33; G06F 30/31; G06F 30/327

(52) U.S. Cl. CPC G06F 30/33; G06F 30/31; G06F 30/327

(57) ABSTRACT

Disclosed subject matter relates to verification and debugging tool and method for selecting signals form RTL code blocks and appending signals to a waveform window. Verification and debugging tool receives RTL code in Hardware Description Language (HDL). Further, verification and debugging tool parses RTL code, and generate abstract syntax tree representing syntactic structure of RTL code. Thereafter, converts abstract syntax tree into RTL directed graph. Furthermore, assign a unique code block identifier (ID) to each of the plurality of code blocks, and store the one or more code blocks, their corresponding code block IDs. Finally, display the template enabling simultaneous visualization of multiple code blocks and corresponding interconnections.

### CROSS-REFERENCE TO RELATED APPLICATIONS

The present application claims the benefit of priority to U.S. Provisional Application No. 63/730,505, filed on Dec. 11, 2024; the contents of which are hereby incorporated by reference herein in their entirety.

### TECHNICAL FIELD

The present disclosure relates to electronic design. Particularly, the present disclosure relates to generating one or more templates for storing Register Transfer Level (RTL) code objects.

### BACKGROUND

Modern electronic design utilizes Computer-Aided Design (CAD) tools or Electronic Design Automation (EDA) systems. To design an Integrated Circuit (IC) device, a designer first creates high-level behavior descriptions of the IC device using a hardware description language (HDL) such as Verilog and VHDL. As the complexity of the IC devices is growing exponentially due to changes such as shrinking in size of the IC chips and integration of more functionality onto a single IC chip, the behavioral descriptions of the devices are also becoming complex due to presence of a large number of HDL code blocks for the IC chips.

A verification engineer usually identifies and resolves the errors or bugs present in the written code blocks using verification and debugging tools. The verification engineer needs to perform multiple iterations in the process of identifying and resolving errors in a RTL code written in text format. With each iteration, the verification engineer may update some particular code blocks while keeping the remaining code blocks unchanged. The existing verification and debugging tools, for each iteration, store the updated code at a new memory location. As the number of iterations increase, the memory requirement to store the RTL code may also increase, which makes the verification process inefficient. Additionally, the existing verification and debugging tools do not provide a global visual view of how logic is structured and data and control flow is structured. Further, the existing verification and debugging tool provide a limited window of visibility into the RTL code and only one signal or a group of signal addition is possible at a time.

Therefore, there is a need for a verification and debugging tool that is capable of storing the updated RTL code efficiently i.e., by utilizing less memory space. Further it is required to represent the RTL code in a global visual view of the RTL code blocks.

The information disclosed in this background of the disclosure section is only for enhancement of understanding of the general background of the invention and should not be taken as an acknowledgement or any form of suggestion that this information forms the prior art already known to a person skilled in the art.

### SUMMARY

Disclosed herein is a verification and debugging tool for Register Transfer Level (RTL) code. The verification and debugging tool comprises an input interface configured to receive RTL code in a Hardware Description Language (HDL). Further, the verification and debugging tool comprises an RTL parser configured to parse the RTL code, and represent one or more code blocks of the RTL code. Thereafter, the verification and debugging tool comprises a graph converter configured to convert the parsed RTL code into an RTL directed graph. The RTL directed graph comprises a plurality of RTL code blocks represented as nodes and each node corresponding to a functional block of the RTL code. Furthermore, the verification and debugging tool comprises a template generator configured to assign a unique code block identifier (ID) to each of the plurality of code blocks, and store the one or more code blocks, their corresponding code block IDs and the flylines in the form of a template. The template is stored in a memory. Finally, the verification and debugging tool comprises a visual display configured to display the template enabling simultaneous visualization of multiple code blocks and corresponding interconnections.

Further, disclosed herein is a method of generating one or more templates for storing Register Transfer Level (RTL) code objects. The method includes receiving RTL code in a Hardware Description Language (HDL). Further, the method includes parsing the RTL code and representing one or more code blocks of the RTL code. Thereafter, the method includes converting the parsed RTL code into an RTL directed graph. The RTL directed graph comprises a plurality of RTL code blocks represented as nodes and each node corresponding to a functional block of the RTL code. Furthermore, the method includes assigning a unique code block identifier (ID) to each of the plurality of code blocks. Thereafter, the method includes storing the one or more code blocks, their corresponding code block IDs, and the flylines in the form of a template. The template is stored in a memory. Finally, the method includes displaying the template enabling simultaneous visualization of multiple code blocks and corresponding interconnections.

Furthermore, the present disclosure relates to a non-transitory computer readable medium including instructions stored thereon that when processed by at least one processor, cause a verification and debugging tool to perform operations comprising receiving RTL code in a Hardware Description Language (HDL). Further, the instructions cause the processor to parse the RTL code, and represent one or more code blocks of the RTL code. Thereafter, the instructions cause the processor to convert the parsed RTL code into an RTL directed graph. The RTL directed graph comprises a plurality of RTL code blocks represented as nodes and each node corresponding to a functional block of the RTL code. Furthermore, the instructions cause the processor to assign a unique code block identifier (ID) to each of the plurality of code blocks, and store the one or more code blocks, their corresponding code block IDs and the flylines in the form of a template. The template is stored in a memory. Finally, the instructions cause the processor to display the template enabling simultaneous visualization of multiple code blocks and corresponding interconnections.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE ACCOMPANYING DRAWINGS

The accompanying drawings, which are incorporated in and constitute a part of this disclosure, illustrate exemplary embodiments and, together with the description, explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and regarding the accompanying figures, in which:

FIG. 1 shows an exemplary environment of generating one or more templates for storing Register Transfer Level (RTL) code objects, in accordance with some embodiments of the present disclosure;

FIG. 2A illustrates a template on the visual canvas, in accordance with some embodiments of the present disclosure;

FIG. 2B illustrates an updated template on the visual canvas, in accordance with some embodiments of the present disclosure;

FIG. 3 shows a flowchart illustrating method of generating one or more templates for storing Register Transfer Level (RTL) code objects, in accordance with some embodiments of the present disclosure; and

FIG. 4 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood that it is not intended to limit the disclosure to the specific forms disclosed, but on the contrary, the disclosure is to cover all modifications, equivalents, and alternative falling within the scope of the disclosure.

The terms “comprises”, “comprising”, “includes”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or identity server proceeded by “comprises . . . a” does not, without more constraints, preclude the existence of other elements or additional elements in the system or method.

The terms like “at least one” and “one or more” may be used interchangeably throughout the description.

The terms like “verification and debugging tool”, “verification tool”, “debugging tool” and “tool” may be used interchangeably throughout the description.

The terms like “RTL code” and “code” may be used interchangeably throughout the description.

The terms like “circuit designer” and “designer” may be used interchangeably throughout the description.

The present disclosure relates to a verification and debugging tool that stores the Register Transfer Level (RTL) code objects in the form of a template. The RTL code is a coding style used in digital system design and computer engineering, that is written using Hardware Description Language (HDL) like Verilog or VHDL. The RTL code defines the functioning of a digital circuit that may include multiple code blocks. In particular, RTL describes how the data transforms and flows from one register to another. The transformation of data is performed by combinational logic that exists between the registers. The operation of the RTL code is verified by using the verification tool and if any errors or problems arise in the code during its operation, the designer and/or verification engineer may use debugging tool to resolve the problems. The tool disclosed in the present disclosure provides a provision to store the objects of the RTL code in an efficient manner in the memory in the form of a template.

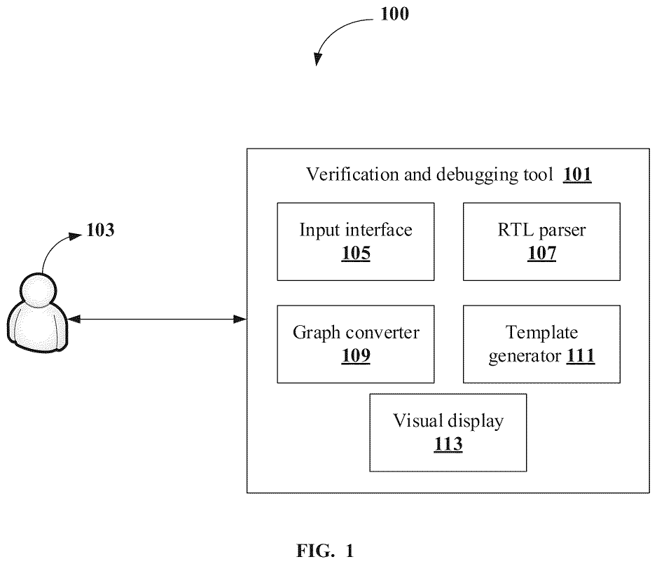

FIG. 1 shows an exemplary environment of generating one or more templates for storing Register Transfer Level (RTL) code objects, in accordance with some embodiments of the present disclosure.

Exemplary environment 100 includes a verification and debugging tool 101 and a user 103. The verification and debugging tool 101 may include an input interface 105, an RTL parser 107, a graph converter 109, an template generator 111, and a visual display 113. The user 103 may interact with the verification and debugging tool 101 using the input interface 105 and the visual display 113. The input interface 105 may include, without limitation, keyboards, mouse, touchscreens, and the like, which allow direct user interaction. The input interface 105 may also receive input from any sources provided by the user 103. As an example, the input interface 105 may receive input from Uniform Resource Locator (URL). The output may be displayed on the visual display 113. As an example, the visual display 113 may include, without limitation, an electronic screen, a touchscreen and the like, which allows display of the output. In an embodiment, the verification and debugging tool 101 may be a computing device. As an example, the computing device may be any device used by the user 103 such as, but not limited to, mobile phones, smartphones, laptops, and Personal Computers (PCs). In some embodiments, the verification and debugging tool 101 may be configured within the computing device (not shown in figure).

In an embodiment, the input interface 105 may be configured to receive RTL code in a Hardware Description Language (HDL) from the user 103. The HDLs may include, without limitation, at least one of Verilog and VHSIC Hardware Description Language (VHDL). As an example, the user 103 may be a circuit designer. The RTL code may describe behavior and component connections of a circuit such as an Integrated Circuit (IC). The RTL code may include one or more code blocks describing the operations of one or more entities/components of the circuit. In an embodiment, the input interface 105 may be further configured to validate syntax of the RTL code. If syntax error is detected, the syntax error may be displayed on the visual display 113 allowing the user 103 to edit the RTL code to rectify the syntax error. The input interface 105 may also detect any error which may affect execution of the RTL code.

In an embodiment, upon receiving the RTL code, the RTL parser 107 may be configured to parse the RTL code and represent one or more code blocks of the RTL code. In an embodiment, the RTL parser 107 may parse the RTL code by performing lexical and syntactic analysis to identify structural elements such as modules, signals, assignments, and control statements.

In an embodiment, upon parsing the RTL code, the graph converter 109 may be configured to convert the parsed RTL code into an RTL directed graph. The RTL directed graph comprises a plurality of RTL code blocks represented as nodes and each node corresponding to a functional block of the RTL code. Each node of the RTL directed graph may include at least one of a forward pointer to nodes for which current node forms an input, and a backward pointer to nodes from which the current node receives the input. The graph converter 109 may be further configured to represent signals of the RTL code as vertices of the RTL directed graph. The graph converter 109 may also provide one or more customizable display options for the RTL directed graph. The one or more customizable option may include, without limitation, at least one of color coding for different types of signals, adjustable node sizes, and selectable layers of data flow representation. The customizable options may enable the user 103 to modify the visual representation of the RTL directed graph to suit specific debugging or analysis requirements. The one or more customizable display options may include, without limitation, color coding for different signal types or logic states, adjustable node sizes to emphasize critical modules, selectable layers for viewing control flow or data flow independently, and variable line thickness or styles to indicate signal width or type. Additional customization may include zoom functionality for detailed inspection of individual nodes, dynamic visual effects to represent changes in signal values over time, and grouping of related nodes into functional sections. These customizable display options enhance clarity, improve navigation within complex RTL designs, and facilitate efficient identification of design issues during verification and debugging. In some embodiments, the RTL directed graph may be configured to display at least one of control flow and data flow. At least one of the control flow and the data flow may be displayed in a visually distinguishable manner. The visual distinction between the control flow and the data flow may be obtained using one of different arrow styles or different colors. In other words, the visual distinction between control flow and data flow within the RTL directed graph is achieved through the use of differentiated graphical indicators. In one embodiment, the distinction is provided by employing different arrow styles, such as solid arrows for data flow and dashed arrows for control flow, or by varying arrowhead shapes to represent signal types. Alternatively, the distinction may be implemented using different colors for the respective flows, enabling clear and intuitive identification of control signals versus data paths. These visual differentiation techniques enhance the readability of complex RTL designs and facilitate efficient debugging and verification by allowing users to quickly interpret the nature of each connection within the graph.

In an embodiment, upon converting the parsed RTL code into the RTL directed graph, the template generator 111 may be configured to assign a unique code block identifier (ID) to each of the plurality of code blocks. Further, the template generator 111 may be configured to store the one or more code blocks, their corresponding code block IDs, and the flylines in the form of a template. The template may be stored in a memory. The template may fix the location of the one or more code blocks and the flylines for visual representation and the template is reusable across multiple analysis sessions. In an embodiment, the template generator 111 may be configured to determine whether the one or more code blocks are changed. Based on the determination, the template generator 111 assigns a new code bock ID to the changed code block while retaining original IDs for unchanged code blocks, wherein the template generator assigns updated code block identifiers starting with a predefined numeric range to differentiate changed code blocks from unchanged code blocks. The template generator 111 may assign new code block identifier for the retained original IDs for unchanged blocks code blocks. The template generator 111 may be configured to assign unique code block identifiers in at least one of incremental numeric order, decremental numeric order, random numeric order, alphanumeric series, or symbolic series. Further, the template generator 111 may maintain a one-to-one mapping between old code block identifiers and new code block identifiers to retain the location and connectivity of code blocks in an updated template. The template generator 111 also stores the flylines representing signal connectivity between code blocks along with corresponding positions on the visual display 113. The template generator 111 automatically generates and stores the template upon detecting an analysis session without requiring manual intervention. As discussed earlier, the memory stores multiple templates corresponding to different analysis goals, each template fixing the location of code blocks and the flylines for intuitive visualization. Updated code blocks are visually distinguishable from unchanged code blocks.

In an embodiment, upon storing the one or more code blocks, the visual display 113 may be configured to display the template enabling simultaneous visualization of multiple code blocks and corresponding interconnections. The visual display 113 and the output interface may also display results in a graphical format. In an embodiment, the visual display 113 may be configured to support zoom functionality for viewing details of individual code blocks or nodes. The zoom functionality may allow the user 103 to focus on specific areas of the RTL directed graph while preserving the ability to return to an overall view. The visual display 113 may also include user interface which may allow the user interactions within the visual display 113. The user interface may allow the user 103 to group multiple code blocks into functional sections. The visual display 113 provides an integrated environment for real-time analysis and debugging of RTL designs. By generating one or more templates for storing Register Transfer Level (RTL) code objects, the verification and debugging tool 101 enhances interpretability of RTL graphs and reduces ambiguity during debugging. This capability enables engineers to track signal name changes across hierarchical levels. As a result, verification workflows become more efficient, accelerating error localization and minimizing the time required to identify and resolve functional issues.

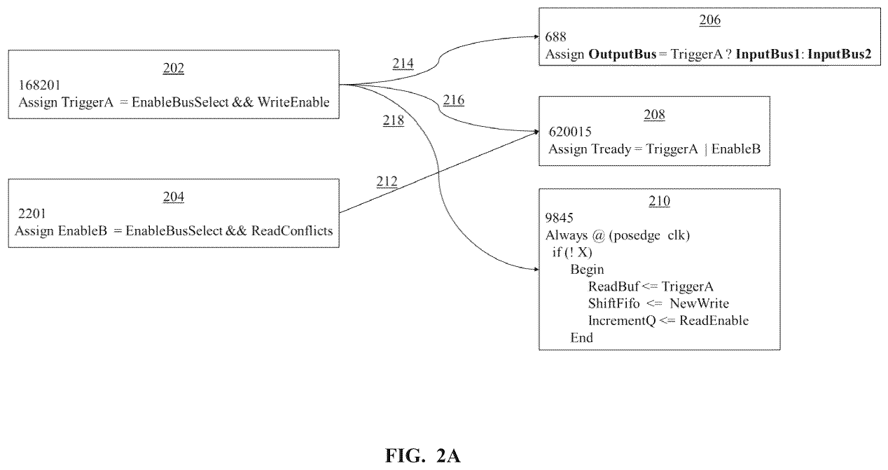

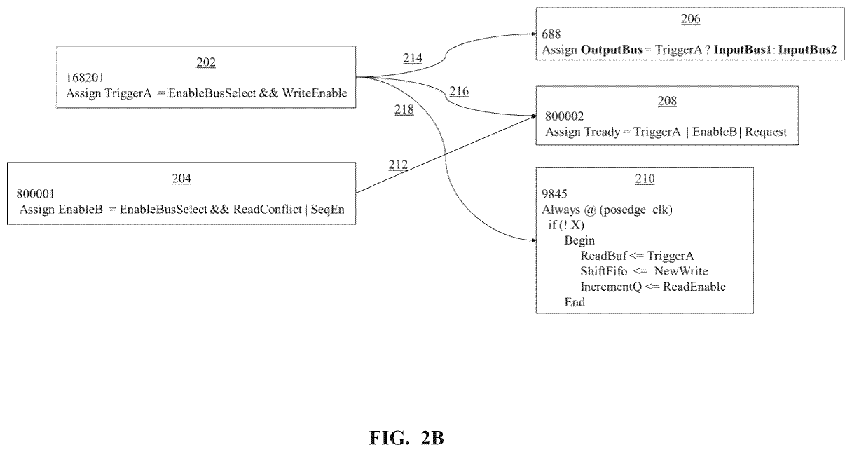

FIG. 2 illustrates a template on the visual canvas, in accordance with an exemplary embodiment of the present disclosure. The stated representation is an exemplary embodiment and should not be construed as a limitation.

The graph converter 109 may display the one or more code blocks 302, 304 . . . , 310 as the RTL DG on the visual canvas. The one or more code blocks 302, 304 . . . , 310 may be connected to each other through flylines 312, 314, 316 and 318.

The template generator 111 may assign the unique ID to each code block of the one or more code blocks. In an exemplary embodiment, the template generator 111 may assign the unique ID to the code blocks in an incremental order of numbers. In another embodiment, the template generator 111 may assign the unique ID to the code blocks in a decremental order of numbers. In yet another embodiment, the template generator 111 may assign the unique ID to the code blocks in a random order of numbers. In another embodiment, the template generator 111 may assign the unique ID to the code blocks in any of the above specified orders of alphanumeric series, alphabetical series and symbolic series, but not limited thereto. It may be appreciated that a designer may provide different options/format to uniquely identify the code IDs. For example, the designer may consider the starting sequence of the code IDs for unchanged block as 1-7 lakhs whereas the starting sequence of the code block IDs for updated code blocks to start with either number 8 lakh or 9 lakhs. Providing uniqueness to code IDs should be the primary objective of the design engineer so that one can differentiate between the status of unchanged and changed/updated code blocks by just checking the code block IDs.

In an exemplary embodiment, the template generator may assign the unique ID to the one or more code blocks 202, 204 . . . , 210 as specified in Table-1 shown below.

TABLE 1
Code blocks and their corresponding
code block IDs saved as a Template

| Code Block | Code Block ID |
|---|---|
| 202 | 168201 |
| 204 | 2201 |
| 206 | 688 |
| 208 | 620015 |
| 310 | 9845 |

The template generator 111 may store the locations of one or more code block ID and flylines 212, 214, 216 and 218 in the form of the template as displayed on the visual canvas. Although table 1 presents the initial provision of assigning code IDs to store the templates however, table 2 presents how the updation in code IDs takes place if the code block is updated.

FIG. 2B illustrates an updated template on the visual canvas, in accordance with an exemplary embodiment of the present disclosure. The stated representation is an exemplary embodiment and should not be construed as a limitation.

The processor may determine that the code lines of the code blocks 204 and 208 are changed by the designer. Thus, the status of the code block is considered as “changed/altered”, in such scenario, the processor may direct the template generator 111 to update the code block ID of the code blocks 204 and 208. However, the processor may not provide any directions to the template generator 111 for alteration of the code IDs for the remaining code blocks 202, 206 and 210. Thus, the code blocks 202,206 and 210 may maintain the same code block ID. Same is presented in the Table 2.

TABLE 2
Code blocks and their corresponding code
block IDs updated in the Template

| | Old Code | New Code | Clock Block |
|---|---|---|---|
| Code Block | Block ID | Block ID | ID Status |
| 202 | 168201 | 168201 | Retained |
| 204 | 2201 | 800001 | Updated |
| 206 | 688 | 688 | Retained |
| 208 | 620015 | 800002 | Updated |
| 210 | 9845 | 9845 | Retained |

While assigning new code block ID to the updated code blocks, the template generator 111 may maintain a 1 to 1 mapping between the code blocks and old code block IDs. Thus, the old template may be transformed by mapping new code block IDs to the old code block IDs which remain unchanged and may allow the location of the code blocks and the flylines to be retained in the new template. The changed RTL blocks may get a new ID which cannot be mapped to the old code block IDs and thus, the updated code blocks can be identified in a fast and easy manner.

In this manner, the template generator 111 may store the updated code block ID of the code blocks 204 and 208 in a new template. In this exemplary embodiment, to clearly differentiate the updated code block ID from the earlier code block ID, the updated code block ID is started with the number 8 lakh whereas the other code block IDs are starting from numbers other than 8 lakhs. Thus, there may be different options or means considered by a designer while assigning the updated Code IDs in a template. In an embodiment, the code blocks that are not changed may retain their location and inter-connectivity (flylines), while the changed code blocks may be indicated visually in a different manner.

Forming and storing templates in a verification tool provides a powerful means to store and optimize the RTL code objects that leads to enhancement of the design process, and also makes efficient utilization of memory space as the code blocks where alteration is not performed are not stored and are managed with the same code IDs. The exemplary scenario may be presented to make the reader understand the subject matter, however, there may be various other aspects and embodiments of the present disclosure as well, other aspects and embodiments will be apparent to those skilled in the art. The various aspects and embodiments disclosed herein are for purposes of illustration and are not intended to be limiting, with the true scope and spirit being indicated by the detailed description.

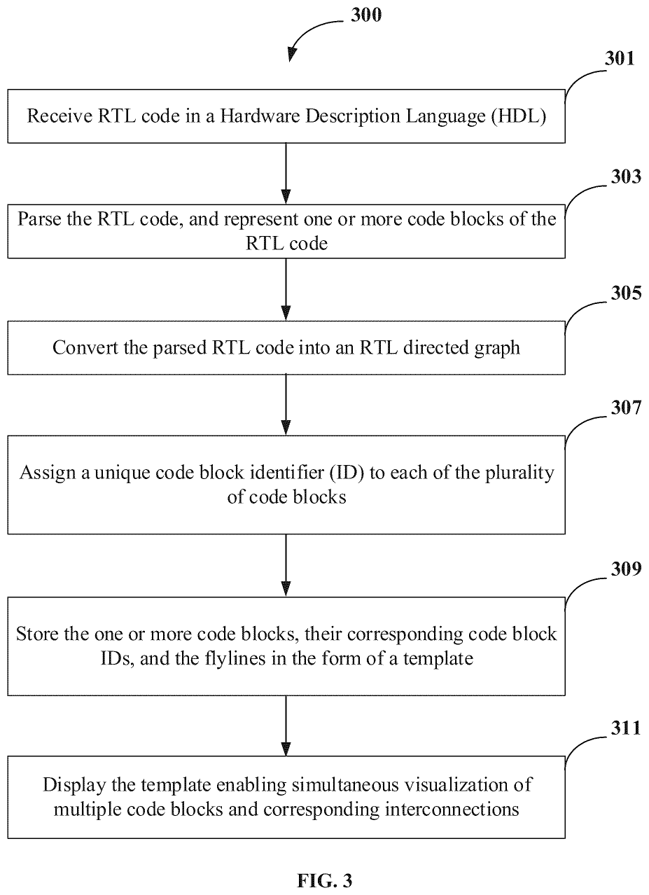

FIG. 3 is a flowchart illustrating a method of generating one or more templates for storing Register Transfer Level (RTL) code objects, in accordance with some embodiments of the present disclosure.

As illustrated in FIG. 3, the method 300 may include one or more blocks illustrating a method of generating one or more templates for storing Register Transfer Level (RTL) code objects, using the verification and debugging tool 101 illustrated in FIG. 1. The method 300 may be described in the general context of computer executable instructions. Generally, computer executable instructions can include routines, programs, objects, components, data structures, procedures, modules, and functions, which perform specific functions or implement specific abstract data types.

The order in which the method 300 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At block 301, the method 300 includes receiving, by a processor of the verification and debugging tool 101, RTL code in a Hardware Description Language (HDL). The HDLs may include at least one of Verilog and VHSIC Hardware Description Language (VHDL). Further, the processor may validate syntax of the RTL code.

At block 303, the method 300 includes parsing, by the processor, the RTL code and represent one or more code blocks of the RTL code.

At block 305, the method 300 includes converting, by the processor, the parsed RTL code into an RTL directed graph. The RTL directed graph comprises a plurality of RTL code blocks represented as nodes and each node corresponding to a functional block of the RTL code. Each node of the RTL directed graph may include at least one of a forward pointer to nodes for which current node forms an input, and a backward pointer to nodes from which the current node receives the input. The processor may represent signals as vertices and flylines to indicate fan-in and fan-out connections between RTL code blocks. Further, the processor may provide one or more customizable display options for the RTL directed graph. The one or more customizable option may include, without limitation, at least one of color coding for different types of signals, adjustable node sizes, and selectable layers of data flow representation. The processor may support zoom functionality for viewing details of individual code blocks or nodes. The zoom functionality may allow a user 103 to focus on specific areas of the RTL directed graph while preserving ability to return to an overall view. The RTL directed graph may be configured to display least one of control flow and data flow, wherein the at least one of the control flow and the data flow is displayed in a visually distinguishable manner.

At block 307, the method 300 includes assigning, by the processor, store, a unique code block identifier (ID) to each of the plurality of code blocks.

At block 309, the method 300 includes storing, by the processor, store the one or more code blocks, their corresponding code block IDs, and the flylines in the form of a template. The template may be stored in a memory. The template may fix the location of the one or more code blocks and the flylines for visual representation and the template is reusable across multiple analysis sessions. In an embodiment, the processor may configure the template generator 111 to determine whether the one or more code blocks are changed. Based on the determination, the processor may configure the template generator 111 to assign a new code bock ID to the changed code block while retaining original IDs for unchanged code blocks, wherein the template generator assigns updated code block identifiers starting with a predefined numeric range to differentiate changed code blocks from unchanged code blocks. The processor may configure the template generator 111 to assign new code block identifier for the retained original IDs for unchanged blocks code blocks. The processor may configure the template generator 111 to assign unique code block identifiers in at least one of incremental numeric order, decremental numeric order, random numeric order, alphanumeric series, or symbolic series. Further, the processor may configure the template generator 111 to maintain a one-to-one mapping between old code block identifiers and new code block identifiers to retain the location and connectivity of code blocks in an updated template. The processor may configure the template generator 111 to store the flylines representing signal connectivity between code blocks along with corresponding positions on the visual display 113. The processor may configure the template generator 111 to automatically generate and store the template upon detecting an analysis session without requiring manual intervention. As discussed earlier, the memory stores multiple templates corresponding to different analysis goals, each template fixing the location of code blocks and the flylines for intuitive visualization. Updated code blocks are visually distinguishable from unchanged code blocks.

At block 311, the method 300 includes displaying, by the processor, display the template enabling simultaneous visualization of multiple code blocks and corresponding interconnections. The processor may configure the visual display 113 to support zoom functionality for viewing details of individual code blocks or nodes. The zoom functionality may allow the user 103 to focus on specific areas of the RTL directed graph while preserving the ability to return to an overall view.

### Computer System

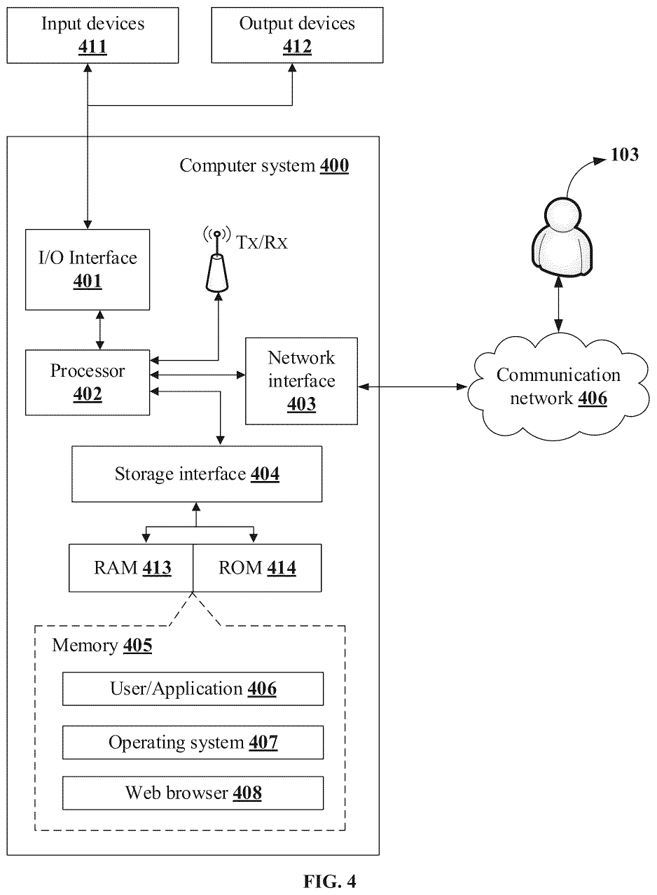

FIG. 4 illustrates a block diagram of an exemplary computer system 400 for implementing embodiments consistent with the present disclosure. In an embodiment, the computer system 400 may be a verification and debugging tool 101 illustrated in FIG. 1. The computer system 400 may include a central processing unit (“CPU” or “processor” or “memory controller”) 402. The processor 402 may comprise at least one data processor for executing program components for executing user- or system-generated business processes. A user may include a network manager, an application developer, a programmer, an organization, or any system/sub-system being operated parallelly to the computer system 400. The processor 402 may include specialized processing units such as integrated system (bus) controllers, memory controllers/memory management control units, floating point units, graphics processing units, digital signal processing units, etc.

The processor 402 may be disposed in communication with one or more Input/Output (I/O) devices (411 and 412) via I/O interface 401. The I/O interface 401 may employ communication protocols/methods such as, without limitation, audio, analog, digital, stereo, IEEE®-1394, serial bus, Universal Serial Bus (USB), infrared, PS/2, BNC, coaxial, component, composite, Digital Visual Interface (DVI), high-definition multimedia interface (HDMI), Radio Frequency (RF) antennas, S-Video, Video Graphics Array (VGA), IEEE® 802.n/b/g/n/x, Bluetooth, cellular (e.g., Code-Division Multiple Access (CDMA), High-Speed Packet Access (HSPA+), Global System For Mobile Communications (GSM), Long-Term Evolution (LTE) or the like), etc. Using the I/O interface 401, the computer system 400 may communicate with one or more I/O devices 411 and 412.

In some embodiments, the processor 402 may be disposed in communication with a network 409 via a network interface 403. The network interface 403 may communicate with the network 409. The network interface 403 may employ connection protocols including, without limitation, direct connect, Ethernet (e.g., twisted pair 10/100/1000 Base T), Transmission Control Protocol/Internet Protocol (TCP/IP), token ring, IEEE® 802.11a/b/g/n/x, etc.

In an implementation, the preferred network 409 may be implemented as one of the several types of networks, such as intranet or Local Area Network (LAN) and such within the organization. The preferred network 409 may either be a dedicated network or a shared network, which represents an association of several types of networks that use a variety of protocols, for example, Hypertext Transfer Protocol (HTTP), Transmission Control Protocol/Internet Protocol (TCP/IP), Wireless Application Protocol (WAP) etc., to communicate with each other. Further, the network 409 may include a variety of network devices, including routers, bridges, RAN nodes, computing devices, storage devices, etc. Using the network interface 403 and the network 409, the computer system 400 may communicate with a user 103.

In some embodiments, the processor 402 may be disposed in communication with a memory 405 (e.g., RAM 413, ROM 414, etc. as shown in FIG. 6) via a storage interface 404. The storage interface 404 may connect to memory 405 including, without limitation, memory drives, removable disc drives, etc., employing connection protocols such as Serial Advanced Technology Attachment (SATA), Integrated Drive Electronics (IDE), IEEE-1394, Universal Serial Bus (USB), fiber channel, Small Computer Systems Interface (SCSI), etc. The memory drives may further include a drum, magnetic disc drive, magneto-optical drive, optical drive, Redundant Array of Independent Discs (RAID), solid-state memory devices, solid-state drives, etc.

The memory 405 may store a collection of program or database components, including, without limitation, user/application interface 406, an operating system 407, a web browser 408, and the like. In some embodiments, computer system 400 may store user/application data 406, such as the data, variables, records, etc. as described in this invention. Such databases may be implemented as fault-tolerant, relational, scalable, secure databases such as Oracle® or Sybase®.

The operating system 407 may facilitate resource management and operation of the computer system 400. Examples of operating systems include, without limitation, APPLE® MACINTOSH® OS X®, UNIX®, UNIX-like system distributions (E.G., BERKELEY SOFTWARE DISTRIBUTION® (BSD), FREEBSD®, NETBSD®, OPENBSD, etc.), LINUX® DISTRIBUTIONS (E.G., RED HAT®, UBUNTU®, KUBUNTU®, etc.), IBM® OS/2® MICROSOFT® WINDOWS® (XP®, VISTA®/7/8, 10 etc.), APPLE® IOS®, GOOGLE™ ANDROID™, BLACKBERRY® OS, or the like.

The user interface 406 may facilitate display, execution, interaction, manipulation, or operation of program components through textual or graphical facilities. For example, the user interface 406 may provide computer interaction interface elements on a display system operatively connected to the computer system 400, such as cursors, icons, check boxes, menus, scrollers, windows, widgets, and the like. Further, Graphical User Interfaces (GUIs) may be employed, including, without limitation, APPLE® MACINTOSH® operating systems' Aqua®, IBM® OS/2®, MICROSOFT® WINDOWS® (e.g., Aero, Metro, etc.), web interface libraries (e.g., ActiveX®, JAVA®, JAVASCRIPT®, AJAX, HTML, ADOBE® FLASH®, etc.), or the like.

The web browser 408 may be a hypertext viewing application. Secure web browsing may be provided using Secure Hypertext Transport Protocol (HTTPS), Secure Sockets Layer (SSL), Transport Layer Security (TLS), and the like. The web browsers 408 may utilize facilities such as AJAX, DHTML, ADOBE® FLASH®, JAVASCRIPT®, JAVA®, Application Programming Interfaces (APIs), and the like. Further, the computer system 400 may implement a mail RAN node stored program component. The mail RAN node may utilize facilities such as ASP, ACTIVEX®, ANSI® C++/C#, MICROSOFT®, .NET, CGI SCRIPTS, JAVA®, JAVASCRIPT®, PERL®, PHP, PYTHON®, WEBOBJECTS®, etc. The mail RAN node may utilize communication protocols such as Internet Message Access Protocol (IMAP), Messaging Application Programming Interface (MAPI), MICROSOFT® exchange, Post Office Protocol (POP), Simple Mail Transfer Protocol (SMTP), or the like. In some embodiments, the computer system 400 may implement a mail client stored program component. The mail client may be a mail viewing application, such as APPLE® MAIL, MICROSOFT® ENTOURAGE® MICROSOFT® OUTLOOK®, MOZILLA® THUNDERBIRD®, and the like.

Furthermore, one or more computer-readable storage media may be utilized in implementing embodiments consistent with the present invention. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., non-transitory. Examples include Random Access Memory (RAM), Read-Only Memory (ROM), volatile memory, nonvolatile memory, hard drives, Compact Disc (CD) ROMs, Digital Video Disc (DVDs), flash drives, disks, and any other known physical storage media.

In light of the technical advancements provided by the disclosed method, the claimed steps, as discussed above, are not routine, conventional, or not well-known aspects in the art, as the claimed steps provide the aforesaid solutions to the technical problems existing in the conventional technologies. Further, the claimed steps clearly bring an improvement in the functioning of the system itself, as the claimed steps provide a technical solution to a technical problem.

The terms “an embodiment”, “embodiment”, “embodiments”, “the embodiment”, “the embodiments”, “one or more embodiments”, “some embodiments”, and “one embodiment” mean “one or more (but not all) embodiments of the invention(s)” unless expressly specified otherwise.

The terms “including”, “comprising”, “having” and variations thereof mean “including but not limited to”, unless expressly specified otherwise.

The enumerated listing of items does not imply that any or all the items are mutually exclusive, unless expressly specified otherwise. The terms “a”, “an” and “the” mean “one or more”, unless expressly specified otherwise.

A description of an embodiment with several components in communication with each other does not imply that all such components are required. On the contrary, a variety of optional components are described to illustrate the wide variety of possible embodiments of the invention.

When a single device or article is described herein, it will be clear that more than one device/article (whether they cooperate) may be used in place of a single device/article. Similarly, where more than one device/article is described herein (whether they cooperate), it will be clear that a single device/article may be used in place of the more than one device/article or a different number of devices/articles may be used instead of the shown number of devices or programs. The functionality and/or features of a device may be alternatively embodied by one or more other devices which are not explicitly described as having such functionality/features. Thus, other embodiments of invention need not include the device itself.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limiting, of the scope of the invention, which is set forth in the following claims.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A verification and debugging tool for Register Transfer Level (RTL) code, the tool comprising:
an input interface configured to receive RTL code in a Hardware Description Language (HDL);
an RTL parser configured to parse the RTL code and represent one or more code blocks of the RTL code;
a graph converter configured to convert the parsed RTL code into an RTL directed graph, wherein the RTL directed graph comprises a plurality of RTL code blocks represented as nodes and each node corresponding to a functional block of the RTL code;
a template generator configured to:
assign a unique code block identifier (ID) to each of the plurality of code blocks; and
store the one or more code blocks, their corresponding code block IDs, and the flylines in the form of a template, wherein the template is stored in a memory;
a visual display configured to display the template enabling simultaneous visualization of multiple code blocks and corresponding interconnections.

2. The verification and debugging tool of claim 1, wherein the template fixes the location of the one or more code blocks and the flylines for visual representation and the template is reusable across multiple analysis sessions.

3. The verification and debugging tool of claim 1, wherein the template generator is configured to:
determine whether the one or more code blocks are changed;
based on the determination, the template generator assigns a new code bock ID to the changed code block while retaining original IDs for unchanged code blocks, wherein the template generator assigns updated code block identifiers starting with a predefined numeric range to differentiate changed code blocks from unchanged code blocks, wherein the template generator assigns new code block identifier for the retained original IDs for unchanged blocks code blocks.

4. The verification and debugging tool of claim 1, wherein the template generator is configured to assign unique code block identifiers in at least one of incremental numeric order, decremental numeric order, random numeric order, alphanumeric series, or symbolic series.

5. The verification and debugging tool of claim 1, wherein the template generator maintains a one-to-one mapping between old code block identifiers and new code block identifiers to retain the location and connectivity of code blocks in an updated template.

6. The verification and debugging tool of claim 1, wherein the template generator stores the flylines representing signal connectivity between code blocks along with corresponding positions on the visual display.

7. The verification and debugging tool of claim 1, wherein the template generator automatically generates and stores the template upon detecting an analysis session without requiring manual intervention.

8. The verification and debugging tool of claim 1, wherein the memory stores multiple templates corresponding to different analysis goals, each template fixing the location of code blocks and the flylines for intuitive visualization.

9. The verification and debugging tool of claim 8, wherein updated code blocks are visually distinguishable from unchanged code blocks.

10. The verification and debugging tool of claim 1, wherein each node of the RTL directed graph comprises at least one of a forward pointer to nodes for which current node forms an input, and a backward pointer to nodes from which the current node receives the input.

11. The verification and debugging tool of claim 1, wherein the graph converter is further configured to represent signals of the RTL code as vertices of the RTL directed graph.

12. The verification and debugging tool of claim 1, further comprising an output interface configured to display debug information related to the RTL code analysis and results.

13. The verification and debugging tool of claim 12, wherein the output interface is configurable to show results in a graphical format.

14. The verification and debugging tool of claim 1, wherein the input interface is further configured to validate syntax of the RTL code.

15. The verification and debugging tool of claim 1, wherein the graph converter is further configured to provide one or more customizable display options for the RTL directed graph, wherein the one or more customizable display options comprises at least one of color coding for different types of signals, adjustable node sizes, and selectable layers of data flow representation.

16. The verification and debugging tool of claim 1, wherein the visual display is configured to support zoom functionality for viewing details of individual code blocks or nodes, wherein the zoom functionality allows a user to focus on specific areas of the RTL directed graph while preserving ability to return to an overall view.

17. The verification and debugging tool of claim 1, further comprises:
a user interface designed to allow user interactions within the visual display.

18. The verification and debugging tool of claim 1, wherein the RTL directed graph is configured to display at least one of control flow and data flow, wherein the at least one of the control flow and the data flow is displayed in a visually distinguishable manner, wherein the visual distinction between the control flow and the data flow is obtained using one of different arrow styles or different colors.

19. A method of generating one or more templates for storing Register Transfer Level (RTL) code objects, the method comprising:
receiving RTL code in a Hardware Description Language (HDL);
parsing the RTL code, and representing one or more code blocks of the RTL code;
converting the parsed RTL code into an RTL directed graph, wherein the RTL directed graph comprises a plurality of RTL code blocks represented as nodes and each node corresponding to a functional block of the RTL code;
assigning a unique code block identifier (ID) to each of the plurality of code blocks;
storing the one or more code blocks, their corresponding code block IDs, and the flylines in the form of a template, wherein the template is stored in a memory; and
displaying the template enabling simultaneous visualization of multiple code blocks and corresponding interconnections.

20. A non-transitory computer readable medium including instructions stored thereon that when processed by at least one processor, cause a verification and debugging tool to perform operations comprising:
receiving RTL code in a Hardware Description Language (HDL);
parsing the RTL code, and representing one or more code blocks of the RTL code;
converting the parsed RTL code into an RTL directed graph, wherein the RTL directed graph comprises a plurality of RTL code blocks represented as nodes and each node corresponding to a functional block of the RTL code;
assigning a unique code block identifier (ID) to each of the plurality of code blocks;
storing the one or more code blocks, their corresponding code block IDs, and the flylines in the form of a template, wherein the template is stored in a memory; and
displaying the template enabling simultaneous visualization of multiple code blocks and corresponding interconnections.
